(19) United States
(12) Patent Application Publication
(10) Pub. No.: US 2017/0186731 A1
(43) Pub. Date: Jun. 29, 2017

(54) SOLID STATE DRIVE OPTIMIZED FOR WAFERS

(71) Applicant: SANDISK TECHNOLOGIES LLC, Plano, TX (US)

(72) Inventor: Atsuyoshi Koike, Tokyo (JP)

(73) Assignee: SANDISK TECHNOLOGIES LLC, Plano, TX (US)

(21) Appl. No.: 15/166,038

(22) Filed: May 26, 2016

Related U.S. Application Data
(60) Provisional application No. 62/387,414, filed on Dec. 23, 2015.

(51) Int. Cl. H01L 25/065; H01L 23/48; H01L 23/02; H01L 25/18; H01L 23/367; H01L 23/00; H01L 23/20; H01L 23/467; H01L 23/473; G11C 29/04; G11C 16/04; H01L 25/00

(52) U.S. Cl. CPC H01L 25/0657; G11C 16/0483; H01L 23/481; H01L 23/02; H01L 25/18; H01L 25/50; H01L 24/14; H01L 23/20; H01L 23/467; H01L 23/473; G11C 29/04; H01L 23/3675; H01L 2225/06541; H01L 2225/06582; H01L 2225/06589; G11C 2029/0403; H01L 27/11556

(57) ABSTRACT

An SSD with a package optimized for semiconductor wafers is configured by thinning a plurality of undiced wafers and stacking the wafers. The wafers are connected to each other by TSV. A subset of the wafers include memory circuits. One of the wafer not in the subset includes peripheral circuits. A casing houses the wafers.

The application claims the benefit of U.S. Provisional Application 62/387,414, filed on Dec. 23, 3015.

### BACKGROUND

Semiconductor memory has been used to make Solid State Drives (SSD). A SSD, also known as a solid-state disk although it contains neither an actual disk nor a drive motor to spin a disk, is a solid-state storage device that uses integrated circuit assemblies as memory to store data persistently. SSDs primarily (but not always) use electronic interfaces compatible with traditional block input/output (I/O) hard disk drives, which permit simple replacements in common applications. Additionally, new I/O interfaces, like SATA Express, have been designed to address specific requirements of the SSD technology.

SSDs have no moving (mechanical) components. This distinguishes them from traditional electromechanical magnetic disks such as hard disk drives (HDDs) or floppy disks, which contain spinning disks and movable read/write heads. Compared with electromechanical disks, SSDs are typically more resistant to physical shock, run silently, have lower access time, less latency and lower power consumption. However, while the price of SSDs has continued to decline over time, consumer-grade SSDs are still more expensive per unit of storage than consumer-grade HDDs.

### BRIEF DESCRIPTION OF THE DRAWINGS

Like-numbered elements refer to common components in the different figures.

FIG. 1 is a perspective view of a 3D stacked non-volatile memory device.

FIG. 2 is a functional block diagram of a memory device such as the 3D stacked non-volatile memory device 100 of FIG. 1.

FIG. 3 is a block diagram depicting one embodiment of a controller.

FIG. 4A is a block diagram of a memory structure having two planes.

FIG. 4B depicts a top view of a portion of a block of memory cells.

FIG. 4C depicts a cross sectional view of a portion of a block of memory cells.

FIG. 4D depicts a view of the select gate layers and word line layers.

FIG. 4E is a cross sectional view of a vertical column of memory cells.

FIG. 4F is a schematic of a plurality of NAND strings.

FIG. 5A shows multiple wafers that are packaged together.

FIG. 5B shows multiple wafers connected together.

FIG. 5C depicts a SSD package.

FIG. 6-1 depicts a reticle.

FIG. 6-2 depicts a reticle.

FIG. 7-1 depicts a semiconductor wafer.

FIG. 7-2 depicts a semiconductor wafer.

FIG. 8 shows multiple wafers that are packaged together.

FIG. 9 depicts a solid state drive.

FIG. 10 depicts one embodiment of multiple groups of stacked semiconductor wafers.

FIG. 11 depicts one embodiment of multiple groups of stacked semiconductor wafers.

FIG. 12 depicts a cross sectional view of one embodiment of multiple groups of stacked semiconductor wafers.

FIG. 13 depicts one embodiment of multiple groups of stacked semiconductor wafers.

FIG. 14 depicts a stack of semiconductor wafers.

### DETAILED DESCRIPTION

Technology is proposed for an SSD with a package optimized for semiconductor wafers. An SSD is configured by thinning a plurality of wafers, stacking the undiced wafers, and connecting the wafers by through silicon vias (TSV). A TSV is a vertical electrical connection (via) passing through a silicon wafer or die. TSVs are a high performance interconnect technique used as an alternative to wire-bond and flip chips to create three dimensional (3D) packages and 3D integrated circuits.

Some SSDs use NAND flash memory (including two dimensional and three dimensional memory structures). However, other forms of non-volatile semiconductor memory can also be used. One technology that can be used to implement memory for an SSD includes charge-trapping material arranged vertically in a 3D stacked memory structure. One example of a 3D memory structure is the Bit Cost Scalable (BiCS) architecture which comprises a stack of alternating conductive and dielectric layers. A memory hole is formed in the stack and a NAND string is then formed by filling the memory hole with materials including a charge-trapping layer to create a vertical column of memory cells. A straight NAND string extends in one memory hole. Control gates of the memory cells are provided by the conductive layers.

The following discussion provides details of one example of a suitable structure for memory devices that can be used to implement a non-volatile memory system for a SSD.

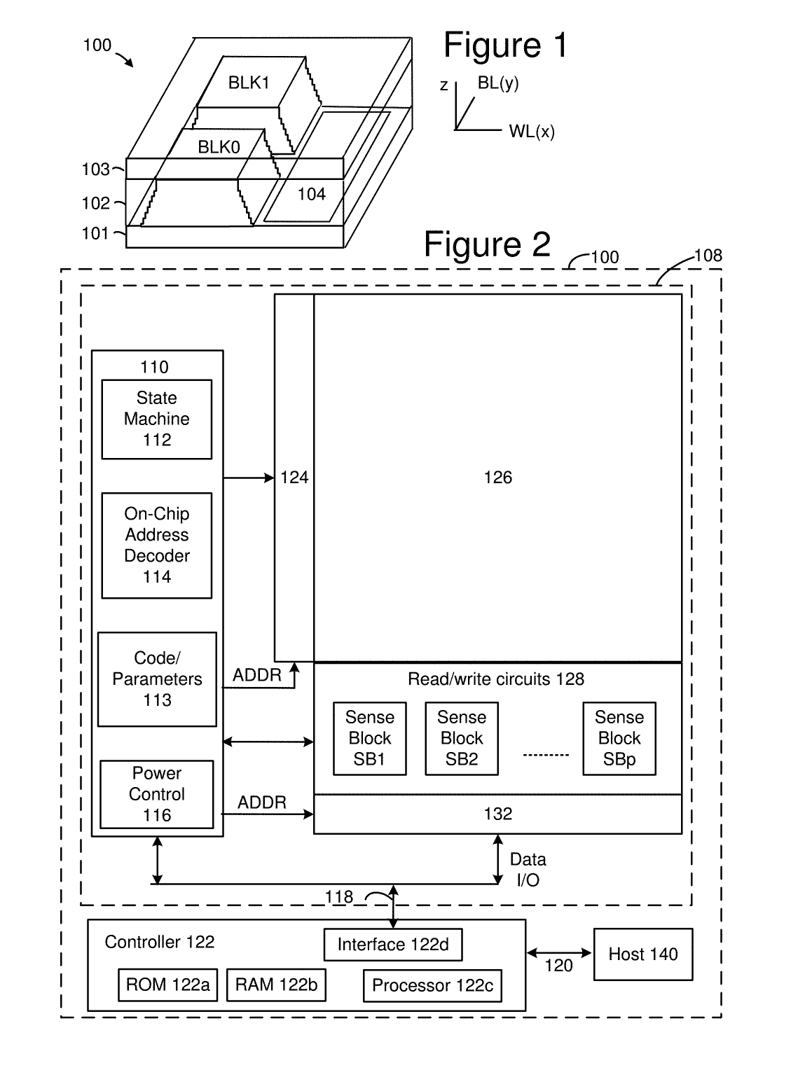

FIG. 1 is a perspective view of a three dimensional (3D) stacked non-volatile memory device. The memory device 100 includes a substrate 101. On and above the substrate are example blocks BLK0 and BLK1 of memory cells (non-volatile storage elements). Also on substrate 101 is peripheral area 104 with support circuits for use by the blocks. Substrate 101 can also carry circuits under the blocks, along with one or more lower metal layers which are patterned in conductive paths to carry signals of the circuits. The blocks are formed in an intermediate region 102 of the memory device. In an upper region 103 of the memory device, one or more upper metal layers are patterned in conductive paths to carry signals of the circuits. Each block comprises a stacked area of memory cells, where alternating levels of the stack represent word lines. While two blocks are depicted as an example, additional blocks can be used, extending in the x- and/or y-directions.

In one example implementation, the length of the plane in the x-direction, represents a direction in which signal paths for word lines extend (a word line or SGD line direction), and the width of the plane in the y-direction, represents a direction in which signal paths for bit lines extend (a bit line direction). The z-direction represents a height of the memory device.

FIG. 2 is a functional block diagram of an example memory device such as the 3D stacked non-volatile memory device 100 of FIG. 1. The components depicted in FIG. 2 are electrical circuits. Memory device 100 includes one or more memory die 108. Each memory die 108 includes a three dimensional memory structure 126 of memory cells (such as, for example, a 3D array of memory cells), control circuitry 110, and read/write circuits 128. In other embodiments, a two dimensional array of memory cells can be used. Memory structure 126 is addressable by word lines via a row decoder 124 and by bit lines via a column decoder 132. The read/write circuits 128 include multiple sense blocks SB1, SB2, . . . , SBp (sensing circuitry) and allow a page of memory cells to be read or programmed in parallel. In some systems, a controller 122 is included in the same memory device 100 (e.g., a removable storage card) as the one or more memory die 108. However, in other systems, the controller can be separated from the memory die 108. In some embodiments the controller will be on a different die than the memory die. In some embodiments, one controller 122 will communicate with multiple memory die 108. In other embodiments, each memory die 108 has its own controller. Commands and data are transferred between the host 140 and controller 122 via a data bus 120, and between controller 122 and the one or more memory die 108 via lines 118. In one embodiment, memory die 108 includes a set of input and/or output (I/O) pins that connect to lines 118.

Memory structure 126 may comprise one or more arrays of memory cells including a 3D array. The memory structure may comprise a monolithic three dimensional memory structure in which multiple memory levels are formed above (and not in) a single substrate, such as a wafer, with no intervening substrates. The memory structure may comprise any type of non-volatile memory that is monolithically formed in one or more physical levels of arrays of memory cells having an active area disposed above a silicon substrate. The memory structure may be in a non-volatile memory device having circuitry associated with the operation of the memory cells, whether the associated circuitry is above or within the substrate.

Control circuitry 110 cooperates with the read/write circuits 128 to perform memory operations (e.g., erase, program, read, and others) on memory structure 126, and includes a state machine 112, an on-chip address decoder 114, and a power control module 116. The state machine 112 provides chip-level control of memory operations. Code and parameter storage 113 may be provided for storing operational parameters and software. In one embodiment, state machine 112 is programmable by the software stored in code and parameter storage 113. In other embodiments, state machine 112 does not use software and is completely implemented in hardware (e.g., electrical circuits).

The on-chip address decoder 114 provides an address interface between addresses used by host 140 or memory controller 122 to the hardware address used by the decoders 124 and 132. Power control module 116 controls the power and voltages supplied to the word lines and bit lines during memory operations. It can include drivers for word line layers (discussed below) in a 3D configuration, select transistors (e.g., SGS and SGD transistors, described below) and source lines. Power control module 116 may include charge pumps for creating voltages. The sense blocks include bit line drivers. An SGS transistor is a select gate transistor at a source end of a NAND string, and an SGD transistor is a select gate transistor at a drain end of a NAND string.

Any one or any combination of control circuitry 110, state machine 112, decoders 114/124/132, code and parameter storage 113, power control module 116, sense blocks SB1, SB2, . . . , SBp, read/write circuits 128, and controller 122 can be considered one or more control circuits that performs the functions described herein.

Any one or any combination of control circuitry 110, state machine 112, decoders 114/124/132, code and parameter storage 113, power control module 116, sense blocks SB1, SB2, . . . , SBp, read/write circuits 128, and controller 122 can be considered peripheral circuits.

The (on-chip or off-chip) controller 122 may comprise a processor 122c, ROM 122a, RAM 122b and a Memory Interface 122d. The storage devices (ROM 122a, RAM 122b) comprises code such as a set of instructions, and the processor 122c is operable to execute the set of instructions to provide the functionality described herein. Alternatively or additionally, processor 122c can access code from a storage device in the memory structure, such as a reserved area of memory cells connected to one or more word lines. Memory interface 122d, in communication with ROM 122a, RAM 122b and processor 122c, is an electrical circuit that provides an electrical interface between controller 122 and memory die 108. For example, memory interface 122d can change the format or timing of signals, provide a buffer, isolate from surges, latch I/O, etc.

Multiple memory elements in memory structure 126 may be configured so that they are connected in series or so that each element is individually accessible. By way of non-limiting example, flash memory devices in a NAND configuration (NAND flash memory) typically contain memory elements connected in series. A NAND string is an example of a set of series-connected memory cells and select gate transistors.

A NAND flash memory array may be configured so that the array is composed of multiple NAND strings of which a NAND string is composed of multiple memory cells sharing a single bit line and accessed as a group. Alternatively, memory elements may be configured so that each element is individually accessible, e.g., a NOR memory array. NAND and NOR memory configurations are exemplary, and memory cells may be otherwise configured.

The memory cells may be arranged in the single memory device level in an ordered array, such as in a plurality of rows and/or columns. However, the memory elements may be arrayed in non-regular or non-orthogonal configurations, or in structures not considered arrays.

A three dimensional memory array is arranged so that memory cells occupy multiple planes or multiple memory device levels, thereby forming a structure in three dimensions (i.e., in the x, y and z directions, where the z direction is substantially perpendicular and the x and y directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory cells. The vertical columns may be arranged in a two dimensional configuration, e.g., in an x-y plane, resulting in a three dimensional arrangement of memory cells, with memory cells on multiple vertically stacked memory planes. Other configurations of memory elements in three dimensions can also constitute a three dimensional memory array.

By way of non-limiting example, in a three dimensional NAND memory array, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

A person of ordinary skill in the art will recognize that the technology described herein is not limited to a single specific memory structure, but covers many relevant memory structures within the spirit and scope of the technology as described herein and as understood by one of ordinary skill in the art.

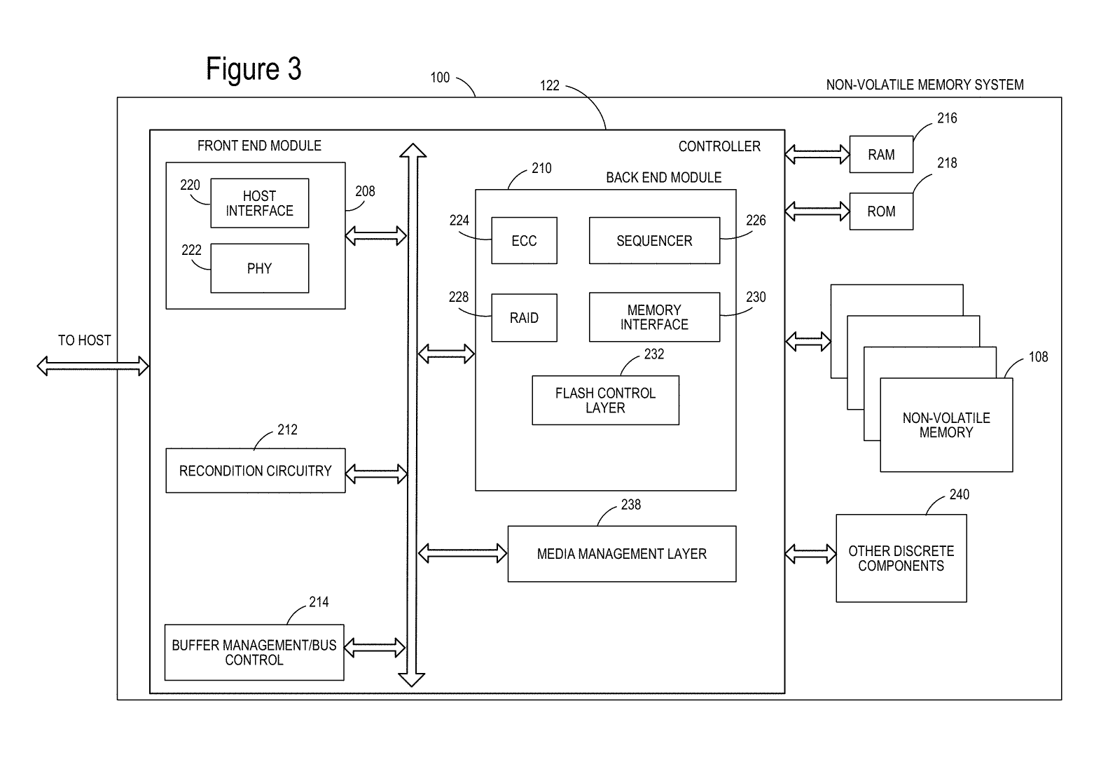

FIG. 3 is a block diagram of example memory system 100, depicting more details of controller 122. As used herein, a flash memory controller is a device that manages data stored on flash memory and communicates with a host, such as a computer or electronic device. A flash memory controller can have various functionality in addition to the specific functionality described herein. For example, the flash memory controller can format the flash memory to ensure the memory is operating properly, map out bad flash memory cells, and allocate spare memory cells to be substituted for future failed cells. Some part of the spare cells can be used to hold firmware to operate the flash memory controller and implement other features. In operation, when a host needs to read data from or write data to the flash memory, it will communicate with the flash memory controller. If the host provides a logical address to which data is to be read/written, the flash memory controller can convert the logical address received from the host to a physical address in the flash memory. (Alternatively, the host can provide the physical address). The flash memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

The interface between controller 122 and non-volatile memory die 104 may be any suitable flash interface, such as Toggle Mode 200, 400, or 800. In one embodiment, memory system 100 may be a card based system, such as a secure digital (SD) or a micro secure digital (micro-SD) card. In an alternate embodiment, memory system 100 may be part of an embedded memory system. For example, the flash memory may be embedded within the host, such as in the form of a solid state disk (SSD) drive installed in a personal computer.

In some embodiments, non-volatile memory system 100 includes a single channel between controller 122 and non-volatile memory die 108, the subject matter described herein is not limited to having a single memory channel. For example, in some memory system architectures, 2, 4, 8 or more channels may exist between the controller and the memory die, depending on controller capabilities. In any of the embodiments described herein, more than a single channel may exist between the controller and the memory die, even if a single channel is shown in the drawings.

As depicted in FIG. 3, controller 112 includes a front end module 208 that interfaces with a host, a back end module 210 that interfaces with the one or more non-volatile memory die 108, and various other modules that perform functions which will now be described in detail.

The components of controller 122 depicted in FIG. 3 may take the form of a packaged functional hardware unit (e.g., an electrical circuit) designed for use with other components, a portion of a program code (e.g., software or firmware) executable by a (micro)processor or processing circuitry that usually performs a particular function of related functions, or a self-contained hardware or software component that interfaces with a larger system, for example. For example, each module may include an application specific integrated circuit (ASIC), a Field Programmable Gate Array (FPGA), a circuit, a digital logic circuit, an analog circuit, a combination of discrete circuits, gates, or any other type of hardware or combination thereof. Alternatively or in addition, each module may include software stored in a processor readable device (e.g., memory) to program a processor for controller 122 to perform the functions described herein. The architecture depicted in FIG. 3 is one example implementation that may (or may not) use the components of controller 122 depicted in FIG. 2 (ie RAM, ROM, processor, interface).

Controller 122 may include recondition circuitry 212, which is used for reconditioning memory cells or blocks of memory. The reconditioning may include refreshing data in its current location or reprogramming data into a new word line or block as part of performing word line maintenance, as described herein.

Referring again to modules of the controller 122, a buffer manager/bus controller 214 manages buffers in random access memory (RAM) 216 and controls the internal bus arbitration of controller 122. A read only memory (ROM) 218 stores system boot code. Although illustrated in FIG. 3 as located separately from the controller 122, in other embodiments one or both of the RAM 216 and ROM 218 may be located within the controller. In yet other embodiments, portions of RAM and ROM may be located both within the controller 122 and outside the controller. Further, in some implementations, the controller 122, RAM 216, and ROM 218 may be located on separate semiconductor die.

Front end module 208 includes a host interface 220 and a physical layer interface (PHY) 222 that provide the electrical interface with the host or next level storage controller. The choice of the type of host interface 220 can depend on the type of memory being used. Examples of host interfaces 220 include, but are not limited to, SATA, SATA Express, SAS, Fibre Channel, USB, PCIe, and NVMe. The host interface 220 typically facilitates transfer for data, control signals, and timing signals.

Back end module 210 includes an error correction controller (ECC) engine 224 that encodes the data bytes received from the host, and decodes and error corrects the data bytes read from the non-volatile memory. A command sequencer 226 generates command sequences, such as program and erase command sequences, to be transmitted to non-volatile memory die 108. A RAID (Redundant Array of Independent Drives) module 228 manages generation of RAID parity and recovery of failed data. The RAID parity may be used as an additional level of integrity protection for the data being written into the non-volatile memory system 100. In some cases, the RAID module 228 may be a part of the ECC engine 224. A memory interface 230 provides the command sequences to non-volatile memory die 108 and receives status information from non-volatile memory die 108. In one embodiment, memory interface 230 may be a double data rate (DDR) interface, such as a Toggle Mode 200, 400, or 800 interface. A flash control layer 232 controls the overall operation of back end module 210.

Additional components of system 100 illustrated in FIG. 3 include media management layer 238, which performs wear leveling of memory cells of non-volatile memory die 108. System 100 also includes other discrete components 240, such as external electrical interfaces, external RAM, resistors, capacitors, or other components that may interface with controller 122. In alternative embodiments, one or more of the physical layer interface 222, RAID module 228, media management layer 238 and buffer management/bus controller 214 are optional components that are not necessary in the controller 122.

The FTL or MML 238 may be integrated as part of the flash management that may handle flash errors and interfacing with the host. In particular, MML may be a module in flash management and may be responsible for the internals of NAND management. In particular, the MML 238 may include an algorithm in the memory device firmware which translates writes from the host into writes to the flash memory 126 of die 108. The MML 238 may be needed because: 1) the flash memory may have limited endurance; 2) the flash memory 126 may only be written in multiples of pages; and/or 3) the flash memory 126 may not be written unless it is erased as a block. The MML 238 understands these potential limitations of the flash memory 126 which may not be visible to the host. Accordingly, the MML 238 attempts to translate the writes from host into writes into the flash memory 126. As described below, erratic bits may be identified and recorded using the MML 238. This recording of erratic bits can be used for evaluating the health of blocks and/or word lines (the memory cells on the word lines).

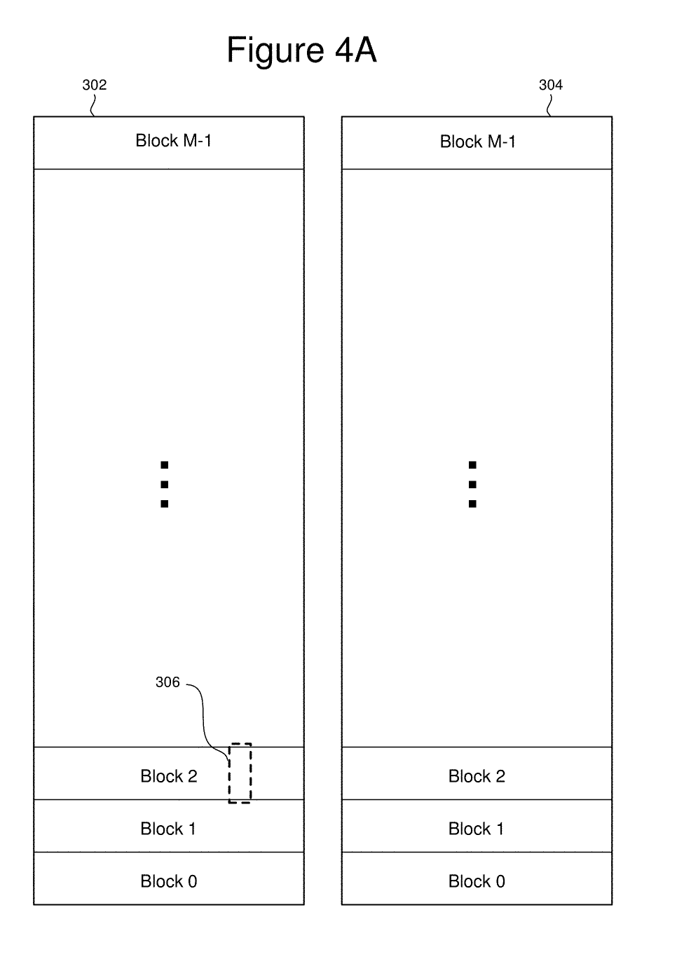

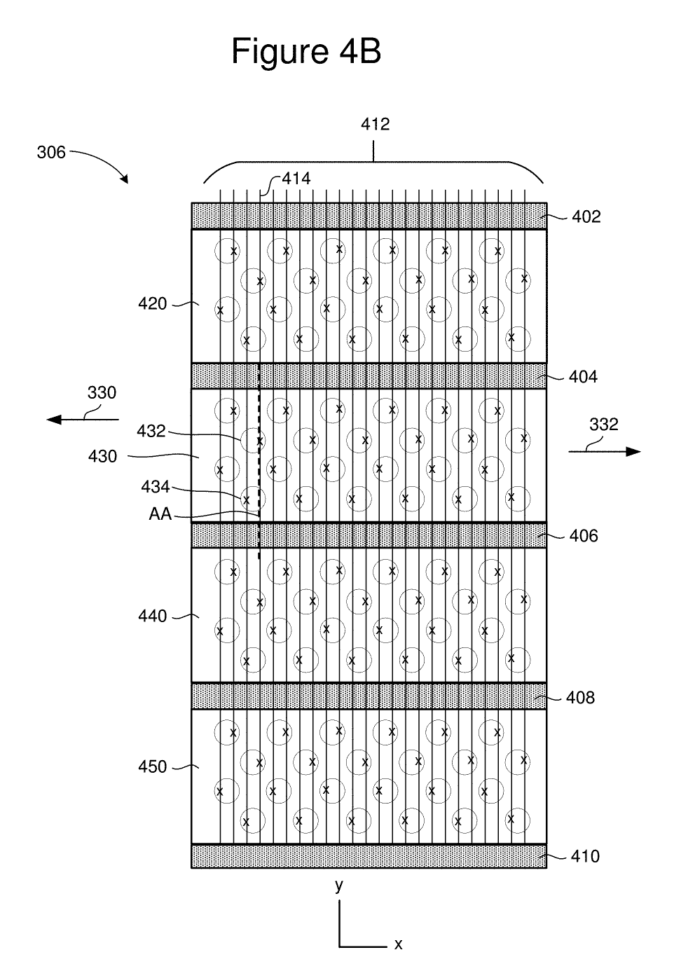

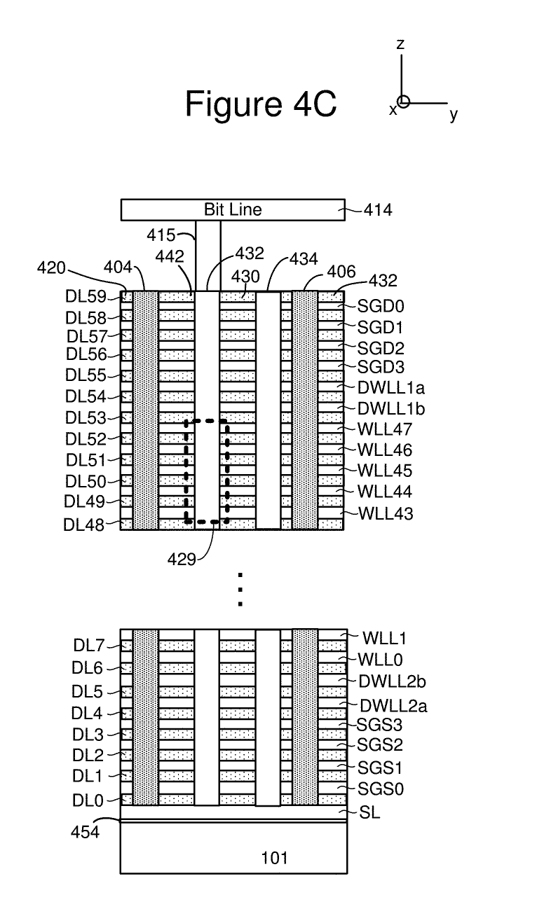

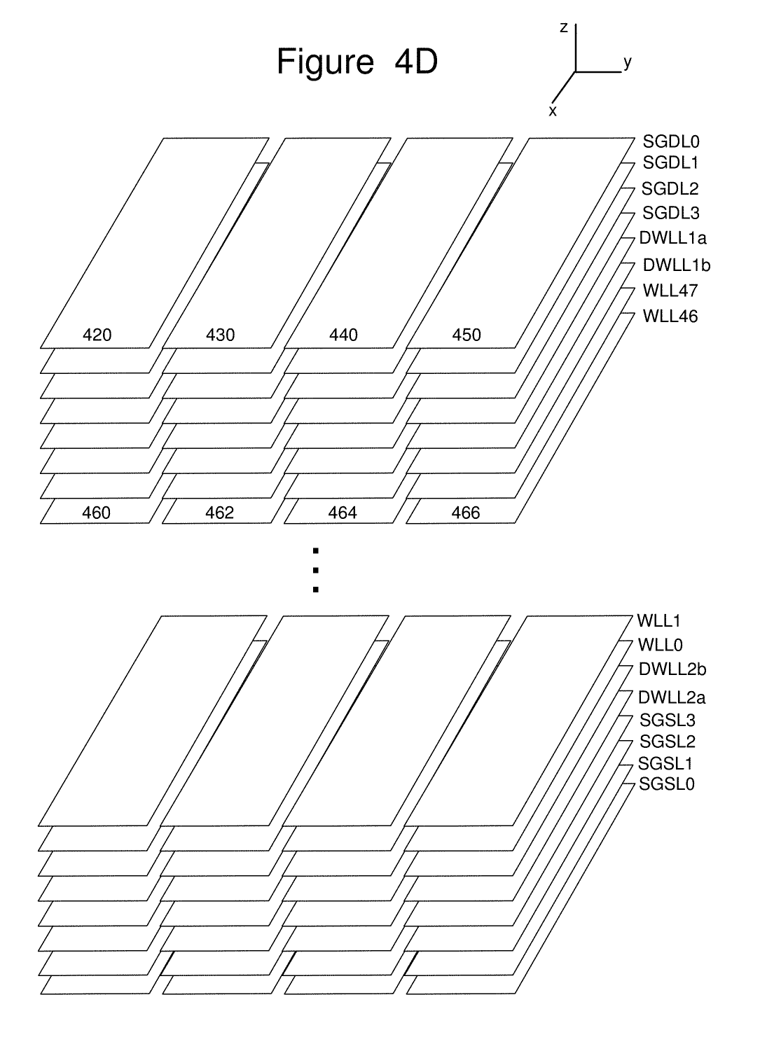

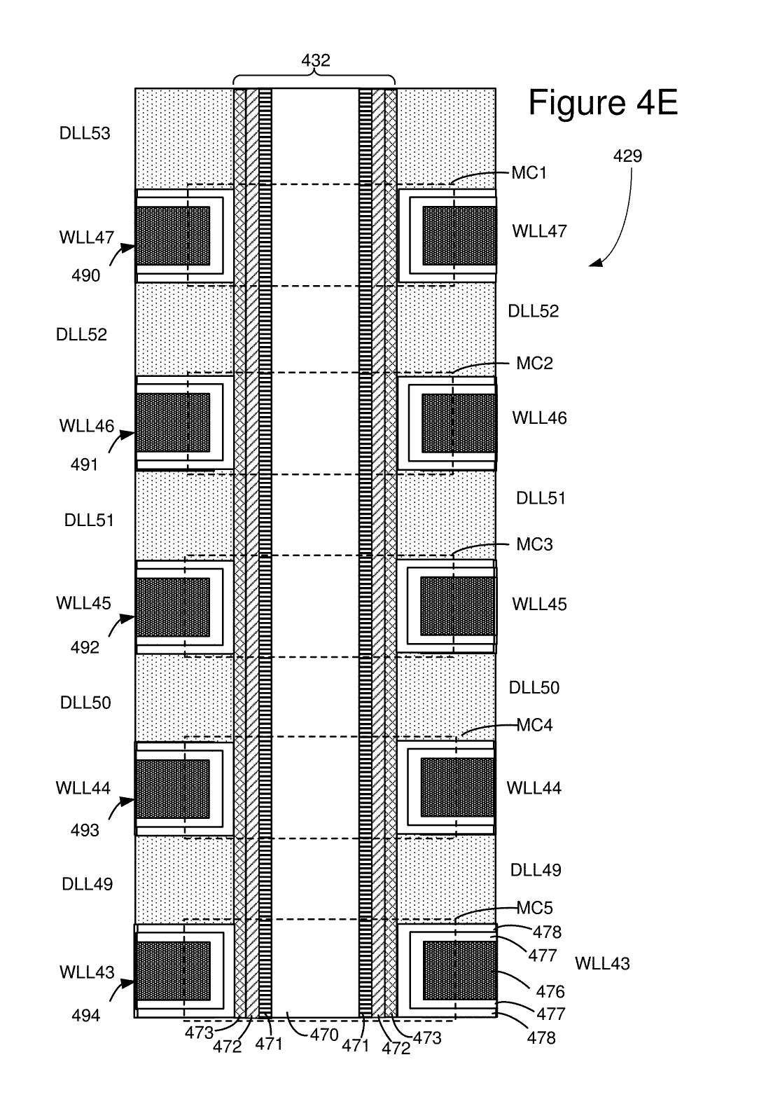

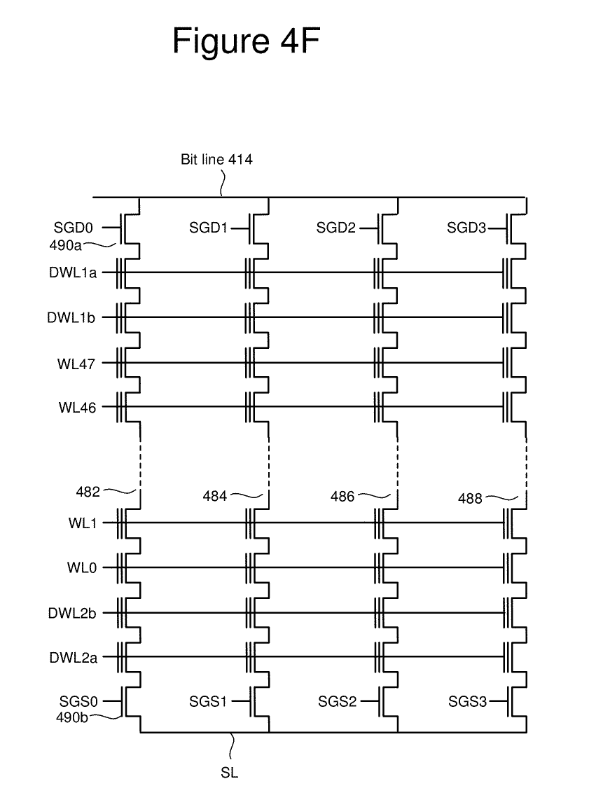

FIG. 4A is a block diagram explaining one example organization of memory structure 126, which is divided into two planes 302 and 304. Each plane is then divided into M blocks. In one example, each plane has about 2000 blocks. However, different numbers of blocks and planes can also be used. For example, some systems may have more than two planes. Other systems may only have one plane.

FIGS. 4B-4E depict an example 3D NAND structure. FIG. 4B is a block diagram depicting a top view of a portion of one block from memory structure 126. The portion of the block depicted in FIG. 4B corresponds to portion 306 in block 2 of FIG. 4A. As can be seen from FIG. 4B, the block depicted in FIG. 4B extends in the direction of arrow 330 and in the direction of arrow 332. In one embodiment, the memory array will have 60 layers. Other embodiments have less than or more than 60 layers. However, FIG. 4B only shows the top layer.

FIG. 4B depicts a plurality of circles that represent the vertical columns. Each of the vertical columns include multiple select transistors and multiple memory cells. In one embodiment, each vertical column implements a NAND string. More details of the vertical columns are provided below. Since the block depicted in FIG. 4B extends in the direction of arrow 330 and in the direction of arrow 332, the block includes more vertical columns than depicted in FIG. 4B

FIG. 4B also depicts a set of bit lines 412. FIG. 4B shows twenty four bit lines because only a portion of the block is depicted. It is contemplated that more than twenty four bit lines connected to vertical columns of the block. Each of the circles representing vertical columns has an “x” to indicate its connection to one bit line.

The block depicted in FIG. 4B includes a set of local interconnects 402, 404, 406, 408 and 410 that connect the various layers to a source line below the vertical columns. Local interconnects 402, 404, 406, 408 and 410 also serve to divide each layer of the block into four regions; for example, the top layer depicted in FIG. 4B is divided into regions 420, 430, 440 and 450, which are referred to as fingers. In the layers of the block that implement memory cells, the four regions are referred to as word line fingers that are separated by the local interconnects. In one embodiment, the word line fingers on a common level of a block connect together at the end of the block to form a single word line. In another embodiment, the word line fingers on the same level are not connected together. In one example implementation, a bit line only connects to one vertical column in each of regions 420, 430, 440 and 450. In that implementation, each block has sixteen rows of active columns and each bit line connects to four rows in each block. In one embodiment, all of four rows connected to a common bit line are connected to the same word line (via different word line fingers on the same level that are connected together); therefore, the system uses the source side select lines and the drain side select lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block.

FIG. 4B also shows the vertical columns being staggered. In other embodiments, different patterns of staggering can be used. In some embodiments, the vertical columns are not staggered.

FIG. 4C depicts a portion of an embodiment of three dimensional memory structure 126 showing a cross-sectional view along line AA of FIG. 4B. This cross sectional view cuts through vertical columns 432 and 434 and region 430 (see FIG. 4B). The structure of FIG. 4C includes four drain side select layers SGD0, SGD1, SGD2 and SGD3; four source side select layers SGS0, SGS1, SGS2 and SGS3; four dummy word line layers DWLL1a, DWLL1b, DWLL2a and DWLL2b; and forty eight data word line layers WLL0-WLL47 for connecting to data memory cells. Other embodiments can implement more or less than four drain side select layers, more or less than four source side select layers, more or less than four dummy word line layers, and more or less than forty eight word line layers. Vertical columns 432 and 434 are depicted protruding through the drain side select layers, source side select layers, dummy word line layers and word line layers. In one embodiment, each vertical column comprises a NAND string. Below the vertical columns and the layers listed below is substrate 101, an insulating film 454 on the substrate, and source line SL. The NAND string of vertical column 432 has a source end at a bottom of the stack and a drain end at a top of the stack. As in agreement with FIG. 4B, FIG. 4C show vertical column 432 connected to Bit Line 414 via connector 415. Local interconnects 404 and 406 are also depicted.

For ease of reference, drain side select layers SGD0, SGD1, SGD2 and SGD3; source side select layers SGS0, SGS1, SGS2 and SGS3; dummy word line layers DWLL1a, DWLL1b, DWLL2a and DWLL2b; and word line layers WLL0-WLL47 collectively are referred to as the conductive layers. In one embodiment, the conductive layers are made from a combination of TiN and Tungsten. In other embodiments, other materials can be used to form the conductive layers, such as doped polysilicon, metal such as Tungsten or metal silicide. In some embodiments, different conductive layers can be formed from different materials. Between conductive layers are dielectric layers DLO-DL59. For example, dielectric layers DL49 is above word line layer WLL43 and below word line layer WLL44. In one embodiment, the dielectric layers are made from SiO₂. In other embodiments, other dielectric materials can be used to form the dielectric layers.

The non-volatile memory cells are formed along vertical columns which extend through alternating conductive and dielectric layers in the stack. In one embodiment, the memory cells are arranged in NAND strings. The word line layer WLL0-WLL47 connect to memory cells (also called data memory cells). Dummy word line layers DWLL1a, DWLL1b, DWLL2a and DWLL2b connect to dummy memory cells. A dummy memory cell does not store user data, while a data memory cell is eligible to store user data. Drain side select layers SGD0, SGD1, SGD2 and SGD3 are used to electrically connect and disconnect NAND strings from bit lines. Source side select layers SGS0, SGS1, SGS2 and SGS3 are used to electrically connect and disconnect NAND strings from the source line SL.

FIG. 4D depicts a logical representation of the conductive layers (SGD0, SGD1, SGD2, SGD3, SGS0, SGS1, SGS2, SGS3, DWLL1a, DWLL1b, DWLL2a, DWLL2b, and WLL0-WLL47) for the block that is partially depicted in FIG. 4C. As mentioned above with respect to FIG. 4B, in one embodiment local interconnects 402, 404, 406, 408 and 410 break up each conductive layers into four regions. For example, word line layer WLL31 is divided into regions 460, 462, 464 and 466. For word line layers (WLL0-WLL31), the regions are referred to as word line fingers; for example, word line layer WLL46 is divided into word line fingers 460, 462, 464 and 466. In one embodiment, the four word line fingers on a same level are connected together. In another embodiment, each word line finger operates as a separate word line.

Drain side select gate layer SGD0 (the top layer) is also divided into regions 420, 430, 440 and 450, also known as fingers or select line fingers. In one embodiment, the four select line fingers on a same level are connected together. In another embodiment, each select line finger operates as a separate word line.

FIG. 4E depicts a cross sectional view of region 429 of FIG. 4C that includes a portion of vertical column 432. In one embodiment, the vertical columns are round and include four layers; however, in other embodiments more or less than four layers can be included and other shapes can be used. In one embodiment, vertical column 432 includes an inner core layer 470 that is made of a dielectric, such as SiO₂. Other materials can also be used. Surrounding inner core 470 is polysilicon channel 471. Materials other than polysilicon can also be used. Note that it is the channel 471 that connects to the bit line. Surrounding channel 471 is a tunneling dielectric 472. In one embodiment, tunneling dielectric 472 has an ONO structure. Surrounding tunneling dielectric 472 is charge trapping layer 473, such as (for example) Silicon Nitride. Other memory materials and structures can also be used. The technology described herein is not limited to any particular material or structure.

FIG. 4E depicts dielectric layers DLL49, DLL50, DLL51, DLL52 and DLL53, as well as word line layers WLL43, WLL44, WLL45, WLL46, and WLL47. Each of the word line layers includes a word line region 476 surrounded by an aluminum oxide layer 477, which is surrounded by a blocking oxide (SiO₂) layer 478. The physical interaction of the word line layers with the vertical column forms the memory cells. Thus, a memory cell, in one embodiment, comprises channel 471, tunneling dielectric 472, charge trapping layer 473, blocking oxide layer 478, aluminum oxide layer 477 and word line region 476. For example, word line layer WLL47 and a portion of vertical column 432 comprise a memory cell MC1. Word line layer WLL46 and a portion of vertical column 432 comprise a memory cell MC2. Word line layer WLL45 and a portion of vertical column 432 comprise a memory cell MC3. Word line layer WLL44 and a portion of vertical column 432 comprise a memory cell MC4. Word line layer WLL43 and a portion of vertical column 432 comprise a memory cell MC5. In other architectures, a memory cell may have a different structure; however, the memory cell would still be the storage unit.

When a memory cell is programmed, electrons are stored in a portion of the charge trapping layer 473 which is associated with the memory cell. These electrons are drawn into the charge trapping layer 473 from the channel 471, through the tunneling dielectric 472, in response to an appropriate voltage on word line region 476. The threshold voltage (Vth) of a memory cell is increased in proportion to the amount of stored charge. In one embodiment, the programming is achieved through Fowler-Nordheim tunneling of the electrons into the charge trapping layer. During an erase operation, the electrons return to the channel or holes are injected into the charge trapping layer to recombine with electrons. In one embodiment, erasing is achieved using hole injection into the charge trapping layer via a physical mechanism such as gate induced drain leakage (GIDL).

FIG. 4F is a logical circuit diagram depicting a plurality of groups of connected programmable and erasable non-volatile memory cells arranged as four NAND strings 482, 484, 486 and 488 connected to bit line 414 and source line SL. The select lines SGD0, SGD1, SGD2, SGD3, SGS0, SGS1, SGS2, AND SGS3 are used to select/unselect the depicted NAND strings. In one embodiment all four drain side select lines (SGD0, SGD1, SGD2, SGD3) connect to each NAND string, but logically only one select line is used to select (actuate) each NAND strings. For example, SGD0 is used to select NAND string 482 to connect NAND string 482 to bit line 414, SGD1 is used to select NAND string 484 to connect NAND string 484 to bit line 414, SGD2 is used to select NAND string 486 to connect NAND string 486 to bit line 414, SGD3 is used to select NAND string 488 to connect NAND string 488 to bit line 414. Similarly, in one embodiment all four drain side select lines (SGS0, SGS1, SGS2, SGS3) connect to each NAND string, but logically only one select line is used to select (actuate) each NAND strings. For example, SGS0 is used to select NAND string 482 to connect NAND string 482 to common source line SL, SGS1 is used to select NAND string 484 to connect NAND string 484 to common source line SL, SGS2 is used to select NAND string 486 to connect NAND string 486 to common source line SL, SGS3 is used to select NAND string 488 to connect NAND string 488 to common source line SL. For example, to connect NAND string 482 to bit line 414, select gate 490b must be turned on (via select line SGD0) and to connect NAND string 482 to source line SL, select gate 490b must be turned on (via select line SGS0).

Although the example memory system discussed above is a three dimensional memory structure that includes vertical NAND strings with charge-trapping material, other (2D and 3D) memory structures can also be used with the technology described herein. For example, floating gate memories (e.g., NAND-type and NOR-type flash memory), ReRAM cross-point memories, magnetoresistive memory (e.g., MRAM), and phase change memory (e.g., PCRAM) can also be used.

One example of a ReRAM cross point memory includes reversible resistance-switching elements arranged in cross point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Magnetoresistive memory (MRAM) stores data by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. This configuration is known as a spin valve and is the simplest structure for an MRAM bit. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCRAM) exploits the unique behavior of chalcogenide glass. One embodiment uses a GeTe-Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. Note that the use of “pulse” in this document does not require a square pulse, but includes a (continuous or non-continuous) vibration or burst of sound, current, voltage light, or other wave.

The above-described technologies can be used to implement memory circuits to be used in an SSD. The memory circuits, peripheral circuits and/or separate controllers (optional) are manufactured on semiconductor wafers, and these wafers are then used to make an SSD. Technology is proposed for an SSD with a package optimized for the semiconductor wafers. In one embodiment, an SSD is configured by thinning a plurality of wafers, stacking the undiced wafers, and connecting the wafers by TSV (through silicon via). By “undiced” it is meant that the wafers have not been cut into separate dies.

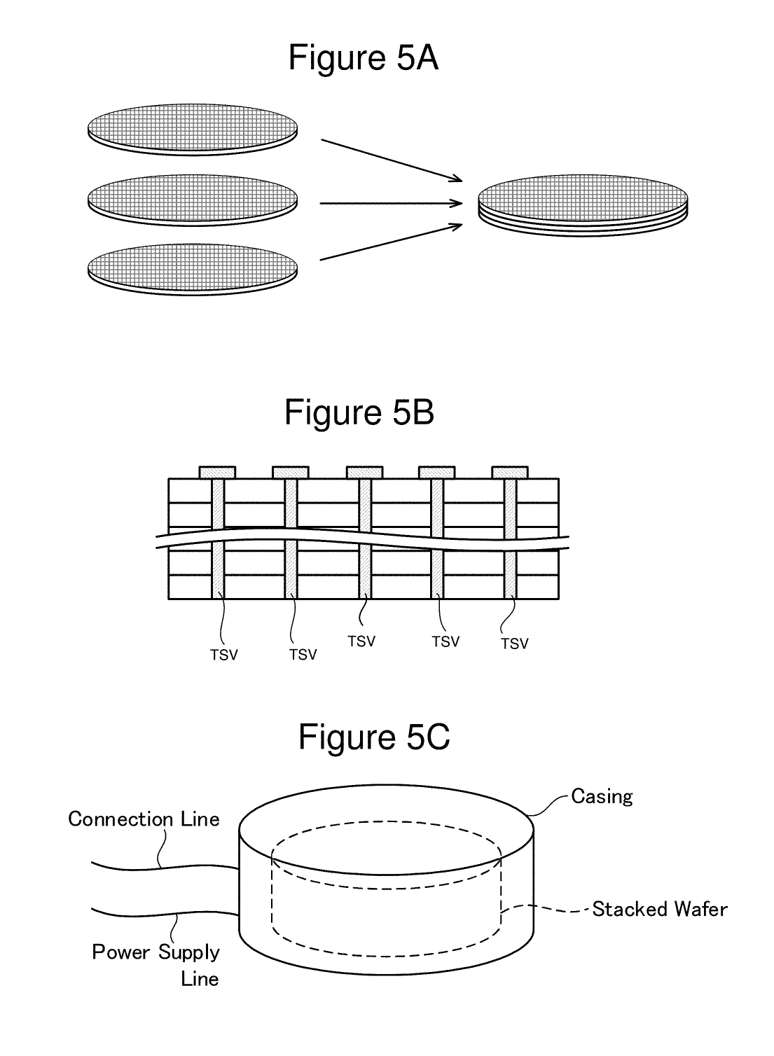

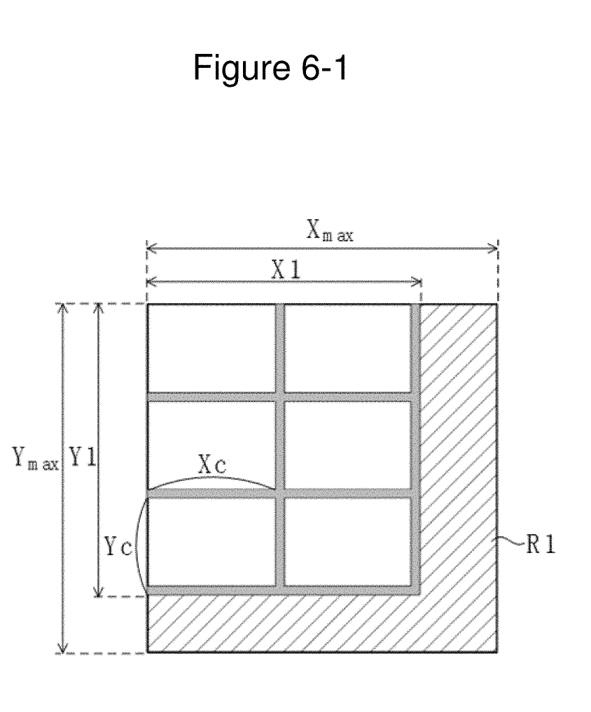

FIGS. 5A, 5B and 5C depict an example SSD and its manufacture processes:

Step 1: Wafers in which flash memories are formed are prepared.
Step 2: The wafers are thinned. The wafers are not diced (not cut into separate dies) and the wafers are stacked on top of each other, and adhered to each other. (See FIG. 5A).
Step 3: The wafers are connected to each other by TSV (through silicon via) (See FIG. 5B)
Step 4: Testing process is performed on the stacked wafers. Memory blocks that are defective and/or of low performance are detected. The SSD is configured such that the detected defective or low performance memory blocks will not be used.
Step 5: The stacked wafers are housed in a Casing that comprises a power supply circuit connected to a Power Supply Line, communication interface connected to a Connection Line, substrate and etc. The casing may have a cylindrical shape (e.g., the same cylindrical shape as the Stacked Wafers) of which diameter is approximately 300 mm (or a different size). (See FIG. 5C).

Traditionally. there has been a need for making the shape of an SSD the same as the shape of a HDD. However, in future, the demand for the SSD itself other than as a replacement for HDDs will be increased. Then, the shape of SSD casing does not need to be matched to the shape of the HDD casing. Therefore, it becomes possible to adopt the casing housing which is optimized with respect to the wafers as in the proposed technology (e.g., cylindrical shape with diameter of approximately 300 mm). The proposed technology is advantageous in a market which does not demand the downsizing of SSD, especially a data center. FIG. 5B shows the Casing that houses the stacked semiconductor wafers as having the same shape as the stacked semiconductor wafers.

There are many advantages to this technology. First, the stacked wafers do not need to be diced into chips. Therefore, it is possible to allow for lower price of SSD because:

(1) Areas required for dicing (e.g., dicing lines) will no longer be required. Effective use of wafer area can be achieved.
(2) Post-processes can be simplified, for example, dicing of chips, testing of chips, and soldering chips to board are no longer performed.

Additionally, the concept of “chips” can be eliminated. Therefore, the degree of freedom for reticle layout can be drastically improved. As a result, the effective area of wafer can be increased. Details will be described herein below.

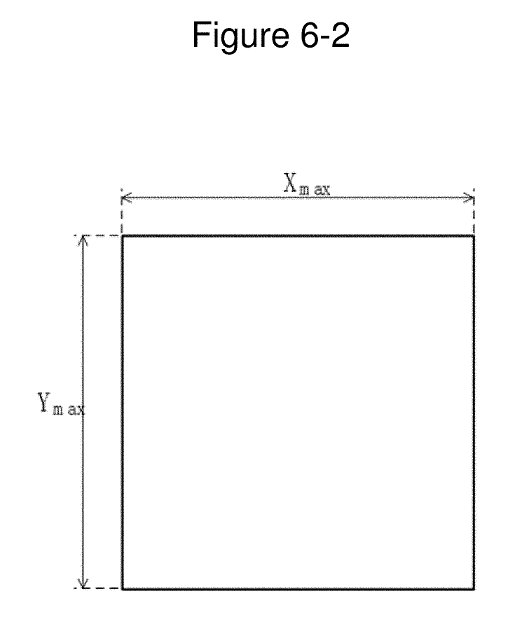

FIG. 6-1 illustrates a conventional reticle. Conventionally, there has been the concept of chips. Due to this, a size X1 and Y1 of the reticle is an integer multiple of a chip size (Xc, Yc). As a result, the size X1 and Y1 of the reticle is undesirably smaller than a maximum size Xmax, Ymax of the reticle. A number of shots will be undesirably increased. The region R! (shaded) may also be wasted.

On the other hand, FIG. 6-2 illustrates a reticle according to the proposed technology. In the proposed technology, there is “not” the concept of chips. Therefore, one circuit can be formed in the region of maximum size Xmax, Ymax. That is, a reticle having the maximum size can inevitably be formed. The number of shots can be minimized No portion of the reticle is wasted.

In a current exposure machine, a region of “26 mm*33 mm” is a maximum region that can be exposed with one shot. In the proposed technology, it becomes possible to repeat the exposure at this maximum size.

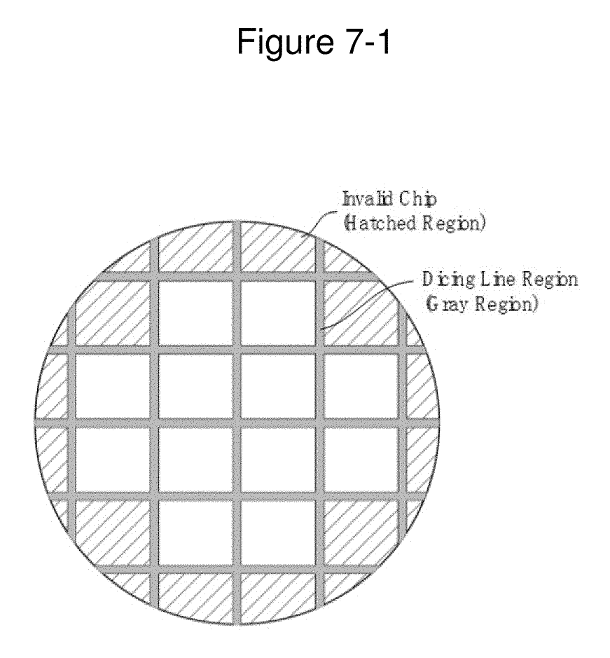

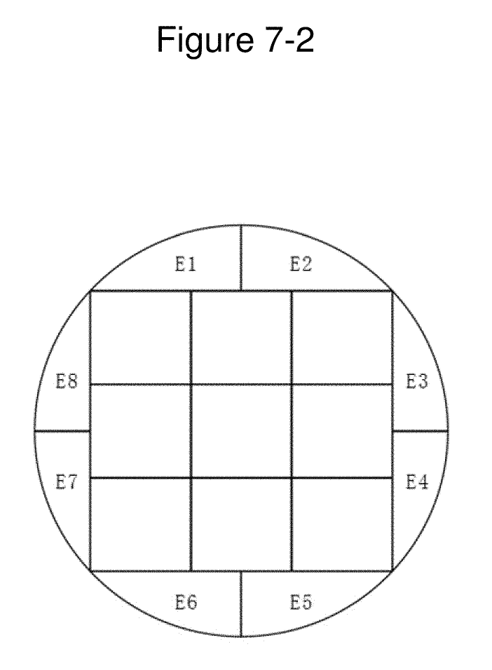

FIG. 7-1 illustrates a conventional wafer layout. Conventionally, there has been the concept of chips. Invalid chip areas are undesirably present at an edge of a wafer (see the hatched region labeled as Invalid Chip). Also, conventionally, there has been the concept of dicing lines. Due to this, an area of dicing lines is included (see the region labeled Dicing Line Region). The effective area of wafer is undesirably decreased due to Invalid Chip areas and Dicing Line Regions.

On the other hand, FIG. 7-2 illustrates a wafer layout according to the proposed technology. In the proposed technology, there is “not” the concept of chips. Therefore, it is possible to use a reticle shape optimized for a shape of the edge regions of the wafer and expose the edge regions of the wafer (see regions E1, E2, E3, E4, E5, E6, E7 and E8). No Invalid Chip areas are generated. Further, in the proposed technology, there is no dicing lines. Therefore, effective use of the entire wafer area can be achieved.

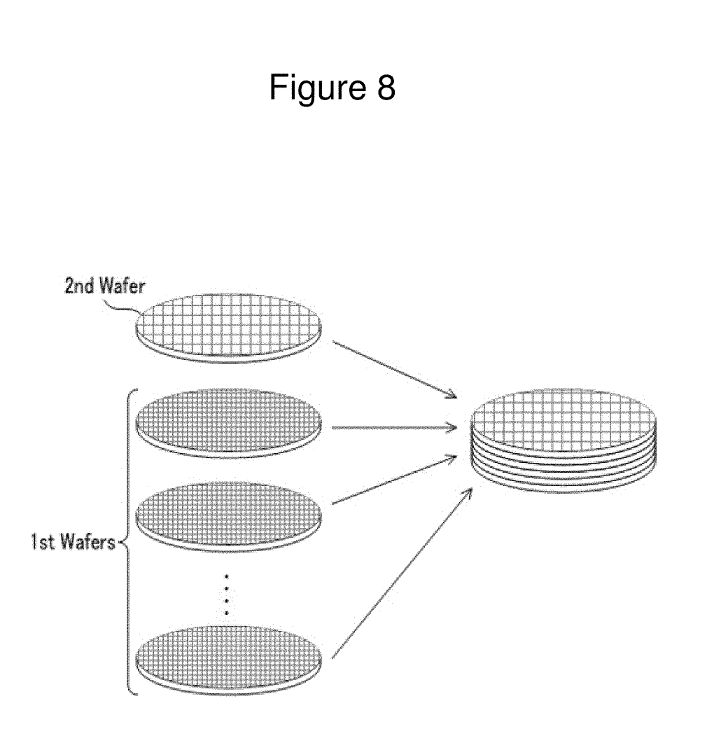

A peripheral circuit and memory cells can be on separate wafers. A plurality of 1st wafers comprising only memory cells is stacked on top of each other. As depicted in FIG. 8, a 2nd wafer comprising only peripheral circuits (optionally including a controller) is arranged on a highest layer of the wafers, above the first wafers. The second wafer and the first wafers are connected by TSV. A controller can be on a 3^{rd} wafer or the SSD will have no controller.

Several kinds of problems undesirably occur if memory cells and a peripheral circuit are formed on a same wafer (e.g., thermal budget of the memory cells gives negative effect on the peripheral circuit). In one embodiment, this problem can be resolved by locating them on different wafers positioned in a common housing.

The above-described technology for staking semiconductor wafers includes a challenge with respect to heat dissipation. For example, the ability to dissipate heat may be low due to the wafers being stacked. Therefore, a structure for cooling is proposed so that data retention lifetime is elongated.

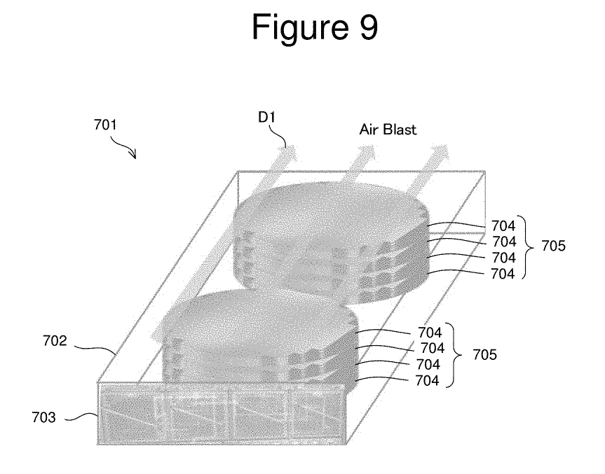

FIG. 9 illustrates a schematic drawing of an SSD 701. In one embodiment, SSD 701 comprises a casing 702, a fan 703, and a plurality of assemblies 705. Air is blown (Air Blast) inside of the casing 702 by fan 703 along the direction D1. Due to this blowing of air, the plurality of assemblies 705 are air-cooled.

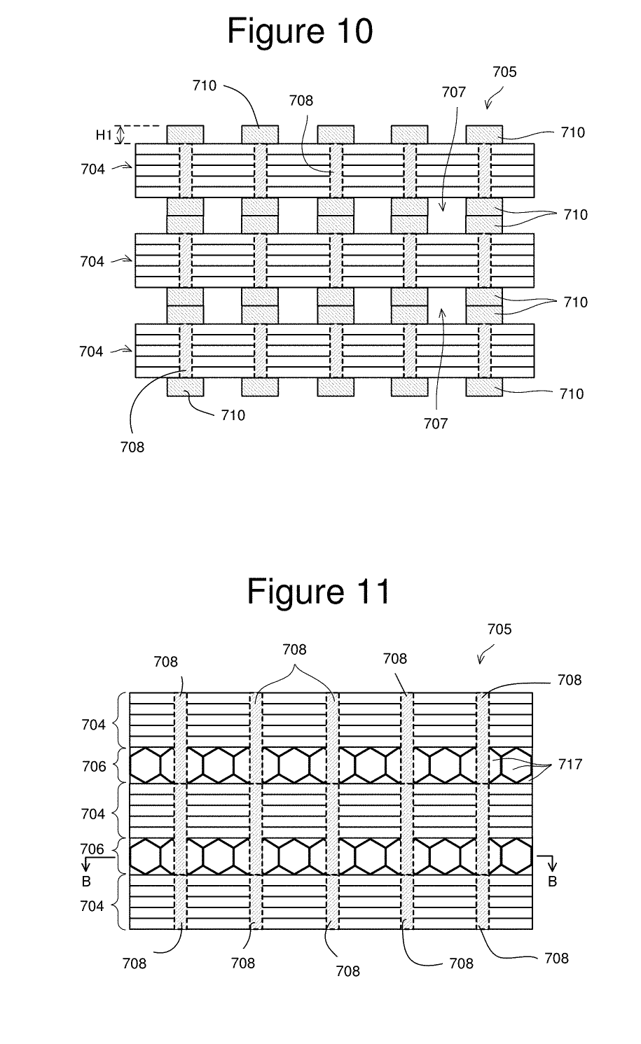

Each one of the assemblies 705 include a plurality of units 704 that are stacked vertically on top of each other. Each unit 704 includes a group of stacked semiconductor wafers. Therefore, one example SSD 701 includes multiple assemblies 705 and each assembly 705 includes multiple groups 704 of stacked semiconductor wafers. In one embodiment, each unit 704 includes a group of 10-20 stacked semiconductor wafers. In other embodiments, different numbers of stacked wafers can be implemented. In one embodiment, units 704 are the stacked wafers described above with respect to FIGS. 5A, 5B and 8 that are electrically connected to adjacent wafers by through silicon vias. In one embodiment of an assembly 705, the units 704 are stacked with ventilation paths between units 704. FIGS. 10-13 depict different embodiments of assemblies 705, showing different strategies for providing the ventilation paths between units 704.

FIG. 10 depicts a first embodiment of an assembly 705. As mentioned above, assembly 705 includes multiple units 704 that are stacked vertically on top of each other and each unit includes multiple stacked semiconductor wafers. Each unit 704 further comprises a plurality of electrically conductive bumps 710 on an upper surface and a plurality of electrically conductive bumps 710 on a lower surface thereof such that bumps 710 on a lower surface of a particular unit 704 are aligned with and bonded to bumps 710 on an upper surface of an adjacent unit 704 with the aligned bumps forming an electrical connection. Therefore, units 704 are electrically connected to each other. Furthermore ventilation holes 707 are formed between the bumps 710 that comprise ventilation paths between units 704. In this embodiment, bumps 710 serve as pillars for arranging the ventilation holes 707 and as heat sinks for releasing heat inside the units 704. Additionally, each unit 704 is depicted in FIG. 10 to include a group of stacked semiconductor wafers that are electrically connected by TSVs 708. Note, however, that only a subset of TSV's 708 and bumps 710 are labeled to prevent the drawing from being cluttered.

In one embodiment, bumps 710 are made of a metal with a high heat conductivity. This will improve the heat sink function that is inherent in the bumps. Further, a height H1 of the bumps 710 can be freely set. Since a cross sectional height of the ventilation holes 707 (ventilation paths) is greater than the height H1 of the bumps, better cooling of the assemblies 705 can be realized.

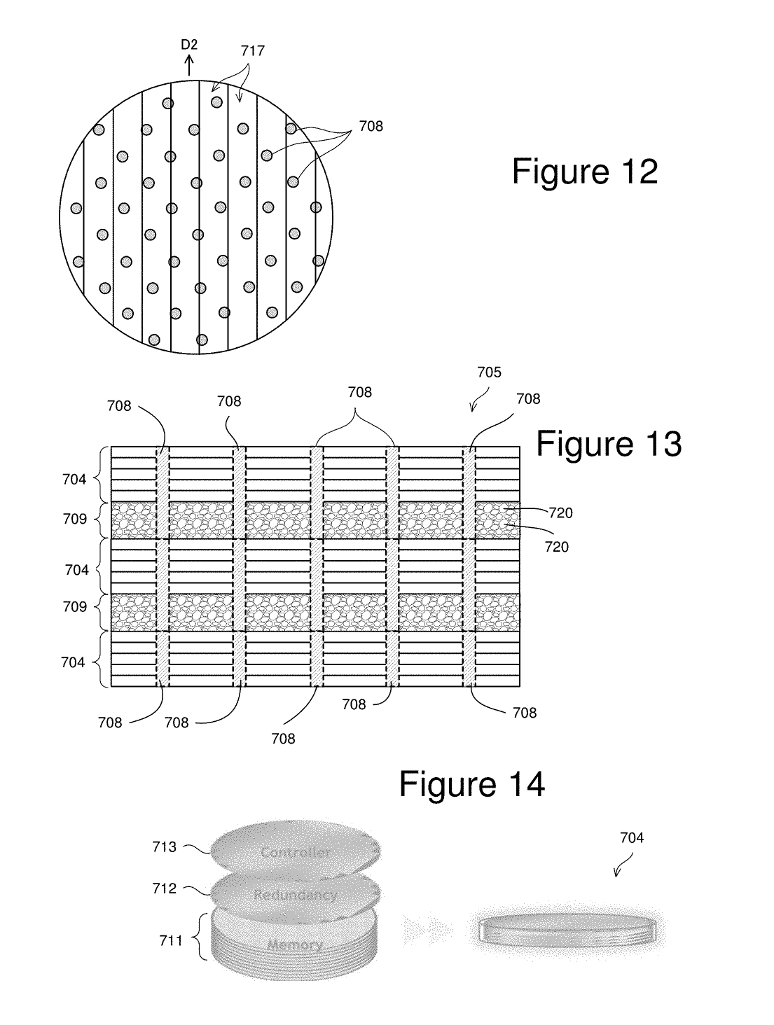

FIGS. 11 and 12 illustrate the second embodiment of an assembly 705. FIG. 11 is a side view. FIG. 12 is a cross sectional view at line B-B of Figurell. FIG. 12 only labels a subset of the TSV 708 to prevent the drawing form being cluttered. Units 704 are stacked with intermediate layers 706 between units 704. The intermediate layers 706 are insulators. Intermediate layers 706 comprise a large number of ventilation holes 717. A plurality of TSV 708 that pass though the undiced semiconductor wafers of units 704 also penetrate and pass through intermediate layers 706. The ventilation holes 717 form ventilation paths for air to flow between the units 704. As shown in FIG. 12, the large number of ventilation holes 717 extend along direction D2. D1 is the air blowing direction, depicted in FIG. 9, that is made to coincide with the D2 direction of FIG. 12 so that the assemblies 705 can be effectively cooled. Several shapes can be implemented as a cross sectional shape of the ventilation holes 717. For example when a hexagonal shape is implemented as shown in FIG. 11, a honeycomb structure can be configured and the strength of the intermediate layers 6 is enhanced.

FIG. 13 illustrates the third embodiment of assemblies 705. Units 704 are stacked via intermediate layers 709. The intermediate layers 709 are an insulator. Tin one embodiment, the intermediate layers 709 comprise many voids (e.g., voids 720) and is structured like a sponge. The voids (which function as ventilation holes) form ventilation paths for air to flow between units 704. A plurality of TSV 708 that pass though the wafers of units 704 also penetrate and pass through the intermediate layers 709. FIG. 13 only labels a subset of voids 720 to prevent the drawing from being cluttered.

FIG. 14 illustrates one embodiment of unit 704 which comprises a group of stacked, undiced and thinned semiconductor wafers connected to each other by TSV. In one example, unit 704 comprises a plurality of semiconductor wafers 711 that comprises only memory cells (e.g., each wafer includes a memory structure 126), a semiconductor wafer 712 for redundancy, and a semiconductor wafer 713 that comprises a peripheral circuits, Controller 126 and/or other one or more control circuits (but no memory cells). In one embodiment, the semiconductor wafers are stacked in the order depicted in FIG. 14 with the plurality of semiconductor wafers 711 on the bottom, the redundancy wafer 712 in the middle and the semiconductor wafer 713 on top. These wafers are connected each other by TSV. In one embodiment, wafer 12 implements the peripheral circuits and wafer 713 implements a Controller 126.

The number of semiconductor wafers 711 that comprises only memory cells can be suitably determined depending on the required capacity. One example is the situation where one semiconductor wafer has a memory volume of 65 TB and an SSD of 128 PB is created. If one unit 704 is formed of twenty semiconductor wafers 711 that comprises only memory cells, that makes 1.28 PB (per unit). If one assembly 705 is formed of ten units 704, that makes 12.8 PB (per assembly). If one SSD is formed of 10 assemblies 705, a large capacity of 128 PB can be realized

In one embodiment, the inside of the casing 702 can be cooled by various methods. The following variations are examples: (1) the casing 702 is sealed and helium gas is filled therein; (2) an air conditioner is mounted in the casing of SSD 701 and cooled air is supplied from the blow fan 703; and/or (3) one or more cooling pipes are inserted in the intermediate layers for transmitting fluids in the ventilation paths so that the assemblies 705 can be water-cooled (or cooled by a different liquid).

One embodiment includes a non-volatile storage system, comprising: a plurality of stacked undiced wafers that each include non-volatile memory cells; and one or more control circuits connected to the memory cells.

One embodiment includes an apparatus, comprising: a plurality of semiconductor wafers connected to each other by through silicon vias, a subset of the wafers include memory circuits, one wafer not in the subset includes peripheral circuits.

One embodiment includes a method, comprising: preparing semiconductor wafers in which flash memory cells are formed; thinning the wafers, the wafers are not diced; stacking the wafers on top of each other and adhering the wafers to each other; connecting the wafers to each other by through silicon vias; and performing a testing process on the stacked wafers.

One embodiment includes a non-volatile storage system, comprising: multiple groups of stacked semiconductor wafers, the groups of stacked semiconductor wafers are stacked with ventilation paths between groups, within each group the semiconductor wafers are electrically connected to adjacent semiconductor wafers by through silicon vias, at least a subset of the semiconductor wafers include non-volatile memory cells.

One embodiment includes a non-volatile storage system, comprising: a plurality of semiconductor wafers that include non-volatile memory cells, the plurality of semiconductor wafers are arranged in stacks; and means for cooling the plurality of semiconductor wafers.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more others parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. A non-volatile storage system, comprising:
a plurality of stacked undiced wafers that each include non-volatile memory cells; and
one or more control circuits connected to the memory cells.

2. The non-volatile storage system of claim 1, wherein:
the wafers include through silicon vias for connecting adjacent wafers.

3. The non-volatile storage system of claim 1, wherein:
the wafers include each include non-volatile memory cells arranged in a three dimensional structure.

4. The non-volatile storage system of claim 1, wherein:
the wafers are thinned.

5. The non-volatile storage system of claim 1, wherein:
the wafers are adhered to each other.

6. The non-volatile storage system of claim 1, wherein:
the wafers do not include dicing lines.

7. The non-volatile storage system of claim 1, wherein:
the wafers do not include invalid chip areas.

8. The non-volatile storage system of claim 1, wherein:
the one or more control circuits include a power supply circuit and a communication interface.

9. The non-volatile storage system of claim 1, further comprising:
a casing for housing the wafers, the wafers are round shaped and the casing is round shaped to match the wafers.

10. The non-volatile storage system of claim 1, further comprising:
an additional wafer stacked with the plurality of stacked undiced wafers, the additional wafer includes the one or more control circuits.

11. An apparatus, comprising:
a plurality of semiconductor wafers connected to each other by through silicon vias, a subset of the wafers include memory circuits, one wafer not in the subset includes peripheral circuits.

12. The apparatus of claim 11, further comprising:
a casing that houses the wafers, the casing is in a same shape as the plurality of semiconductor wafers.

13. The apparatus of claim 11, wherein:
the plurality of semiconductor wafers are undiced.

14. An method, comprising:
preparing semiconductor wafers in which flash memory cells are formed;
thinning the wafers, the wafers are not diced;
stacking the wafers on top of each other and adhering the wafers to each other;
connecting the wafers to each other by through silicon vias; and
performing a testing process on the stacked wafers.

15. The method of claim 14, wherein:
the preparing semiconductor wafers creates the semiconductor wafers without dicing lines and invalid chip areas.

16. The method of claim 14, wherein:
the preparing semiconductor wafers includes using a reticle to exposes edge regions of the wafer for flash memory cells.

17. The method of claim 14, wherein:
the preparing semiconductor wafers includes using a reticle to expose a single layout for each die.

18. A non-volatile storage system, comprising:
multiple groups of stacked semiconductor wafers, the groups of stacked semiconductor wafers are stacked with ventilation paths between groups, within each group the semiconductor wafers are electrically connected to adjacent semiconductor wafers by through silicon vias, at least a subset of the semiconductor wafers include non-volatile memory cells.

19. The non-volatile storage system of claim 18, further comprising:
conductive bumps mounted on an upper surface and a lower surface of the groups such that bumps on a lower surface of a particular group are aligned with and bonded to bumps on an upper surface of an adjacent group with the aligned bumps forming an electrical connection between groups, the ventilation paths are between the bumps. the bumps function as heat sinks for the groups.

20. The non-volatile storage system of claim 19, wherein:
a cross sectional height of the ventilation paths is greater than a height of the conductive bumps.

21. The non-volatile storage system of claim 18, further comprising:
intermediate layers between the groups, the intermediate layers include ventilation holes that form the ventilation paths between groups, the through silicon vias extend through the intermediate layers, the intermediate layers are insulators.

22. The non-volatile storage system of claim 18, further comprising:
sponge structured intermediate insulation layers between groups that include voids which form the ventilation paths between groups, the through silicon vias penetrate the insulation layers.

23. The non-volatile storage system of claim 18, further comprising:
a fan; and
a casing for housing the fan and the groups.

24. The non-volatile storage system of claim 23, wherein:
the casing is sealed and filled with a gas.

25. The non-volatile storage system of claim 22, further comprising:
an air conditioner mounted in the casing.

26. The non-volatile storage system of claim 22, further comprising:
cooling pipes for transmitting fluids in the ventilation paths.

27. The non-volatile storage system of claim 22, wherein:
the multiple groups of stacked semiconductor wafers, the fan and the casing form a solid state drive.

28. A non-volatile storage system, comprising:
a plurality of semiconductor wafers that include non-volatile memory cells, the plurality of semiconductor wafers are arranged in stacks; and
means for cooling the plurality of semiconductor wafers.
